(19) United States
(12) Patent Application Publication
(10) Pub. No.: US 2005/0236667 A1
(43) Pub. Date: Oct. 27, 2005

(54) Manufacture of semiconductor device with selective amorphousizing

(75) Inventors: Kenichi Goto, Hsinchu (TW); Hiroshi Morioka, Kawasaki (JP); Manabu Kojima, Kawasaki (JP); Kenichi Okabe, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/169,666

(22) Filed: Jun. 30, 2005

Related U.S. Application Data
(63) Continuation of application No. PCT/JP03/06898, filed on May 30, 2003.

(51) Int. Cl. H01L 29/45

(52) U.S. Cl. 257/344

(57) ABSTRACT

A p-channel MOS transistor capable of lowering the height of a gate electrode, suppressing penetration of boron through a gate insulating film, and reducing a source/drain parasitic capacitance. A method for manufacturing a semiconductor device comprises the steps of: (a) forming a gate insulating film on each surface of active regions including an n-type active region; (b) depositing a poly-Si gate electrode layer on the gate insulating film; (c) implanting amorphousizing ions, Ge or Si, to transform an upper portion of the gate electrode layer into amorphous phase; (d) patterning the gate electrode layer to form a gate electrode; (e) forming side wall spacers on side walls of the gate electrode at a temperature not crystallizing the amorphous layer; and (f) implanting p-type impurity ions, B, into the n-type active region by using as a mask the gate electrode and the side wall spacers, to form high concentration source/drain regions.

### CROSS REFERENCE TO RELATED APPLICATION

This application is a continuation application of an international patent application, PCT/JP2003/006898, filed on Mary 30, 2003, the entire contents of which are incorporated herein by reference.

### BACKGROUND OF THE INVENTION

A) Field of the Invention

The present invention relates to a semiconductor device and its manufacture method, and more particularly to a semiconductor device including minute transistors and its manufacture method.

B) Description of the Related Art

The integration degree of semiconductor integrated circuit devices is improved more and more. For high integration degree, transistors as constituent elements are made finer. Under the present developments, the gate length of a CMOS transistor formed by 90 nm rules is 40 nm or shorter. As a transistor is miniaturized, the short channel effects appear such as leak current due to punch-through.

In order to prevent the short channel effects, the source/drain regions are formed by extension regions having a shallow junction and outer source/drain regions having a deep junction. Even if shallow extension regions are formed by short range ion implantation, subsequent heat treatment at a high temperature diffuses doped impurities and deepens the junction depth.

It is therefore desired to perform heat treatment such as activation after the ion implantation process at a low temperature. As impurities are activated by a low temperature process, insufficient activation occurs and a transistor drive current may lower.

In order to prevent the punch-through between source/drain regions, the shallow extension regions are covered in some cases with pocket (halo) regions having a conductivity type opposite to that of the extension regions. For example, the pocket region is formed by ion implantation oblique to a substrate normal direction.

In order to realize a high performance semiconductor integrated circuit device, it is desired to improve the integration degree and retain or increase a transistor drive current.

FIGS. 5A to 5C illustrate a p-channel MOS transistor manufacture method according to the basics of conventional manufacture techniques.

As shown in FIG. 5A, in the surface layer of a silicon substrate 101, an element isolation region 102 is formed by shallow trench isolation (STI). Impurity ions for well formation, parasitic capacitance suppression, threshold value adjustment and the like are implanted into an active region defined by the element isolation region to form an n-type well 104.

After a clean surface of the active region 104 is exposed, the silicon surface is thermally oxidized to form a gate insulating film 105. Thereafter, on the gate insulating film 105, a gate electrode layer 106 of polysilicon is deposited by chemical vapor deposition (CVD).

As shown in FIG. 5B, a photoresist layer is coated on the gate electrode layer, exposed and developed to form a resist mask of a gate electrode pattern. The polysilicon layer 106 is etched to form a gate electrode Gp. The resist mask is thereafter removed. By using the patterned gate electrode Gp as a mask, p-type impurity ions are implanted into the n-type well 104 to form source/drain shallow extension regions 111.

As shown in FIG. 5C, an insulating layer of silicon oxide is deposited on the whole surface of the silicon substrate 101, and the insulating layer on the flat surface is removed by anisotropic etching such as reactive ion etching (RIE). Side wall spacers SW are therefore left on the side walls of the gate electrode Gp. The silicon substrate surfaces are exposed outside the side wall spacers SW.

By using the gate electrode Gp and side wall spacers SW as a mask, p-type impurity ions are implanted deeply into the active region 104 to form deep high concentration source/drain regions 114. In this manner, a p-channel MOS (PMOS) transistor is formed. In manufacturing a CMOS device, each ion implantation process is performed independently by separating an n-channel MOS (nMOS) region and pMOS region with resist masks.

As a transistor is miniaturized, the gate length becomes short. If the conventional gate height is to be used, the gate height is too high so that it becomes unstable. As the scaling of transistors advances, it is desired to lower the gate height.

Boron (B) is mainly used as the p-type impurity of a pMOS transistor. As the gate height is lowered, in the process of implanting p-type impurity ions B for forming deep source/drain regions, the phenomenon occurs in which B ions implanted into the gate electrode pierce through the gate insulating film and reach the channel region. New countermeasures are desired to prevent B ions from piercing through the gate insulating film.

FIGS. 6A to 6C illustrate a p-channel MOS transistor manufacture method according to conventional techniques in which B ions can be prevented from piercing through the gate insulating film while a gate electrode height is made low.

As shown in FIG. 6A, after an element isolation region 102 is formed in a silicon substrate 101 by STI, ion implantation is performed to form an n-type well 104. A gate oxide film 105 is formed on the surface of the n-type well 104, and a gate electrode 106 is formed on the gate oxide film 105. The height of the gate electrode 106 is made low because of miniaturization of the transistor.

By using the gate electrode 106 as a mask, p-type impurity ions B are implanted at a low acceleration energy to form shallow p-type extensions 111. Since ion implantation is performed at a low acceleration energy, the phenomenon is hard to occur in which B ions implanted into the gate electrode 106 pierce through the gate oxide film 105.

As shown in FIG. 6B, after side wall spacers SW are formed on the side walls of the gate electrode Gp, Ge ions are implanted to conduct pre-amorphousizing. An upper portion of the gate electrode Gp is therefore transformed into an amorphous layer 109. The polysilicon layer 106 is left in a lower portion of the gate electrode Gp. Ge ions are also doped into the active region 104 so that amorphous layers 118 are formed outside the side wall spacers.

As shown in FIG. 6C, p-type impurity ions B are implanted into the gate electrode Gp and the active region 104 outside the side wall spacers SW to form high concentration p-type source/drain regions.

Since the upper portion of the gate electrode Gp is the amorphous layer 109, an ion implantation depth is constrained so that B ions are prevented from piercing through the gate oxide film. Since the amorphous layers are formed also in the active region 104, the ion implantation depth is constrained so that high concentration source/drain regions 114s having a constrained junction depth are formed.

Thereafter, implanted impurity ions are activated to complete a PMOS transistor. With this manufacture method, since the implantation depth of p-type impurity ions B is constrained, the phenomenon of piercing of B through the gate insulating film can be prevented.

However, the implantation depth of the high concentration source/drain regions is also constrained. An impurity concentration gradient of the high concentration source/drain regions becomes sharp. It is difficult for a depletion layer to widen when a negative voltage is applied to the drain region, so that parasitic capacitances of the source/drain regions increase. An increase in parasitic capacitance results in a lowered operation speed.

For example, Japanese Patent Laid-open Publication No. HEI-9-23003 discloses a pMOS transistor manufacture method in which after a gate electrode is formed, In ions are implanted to form p-type extension regions, side wall spacers are formed, Si ions are implanted for channeling prevention, and thereafter B ions are implanted to form high concentration source/drain regions.

### SUMMARY OF THE INVENTION

An object of the present invention is to provide a semiconductor device manufacture method capable of forming a micro pMOS transistor which can operate at high speed and has a large drive current.

Another object of the present invention is to provide a semiconductor device manufacture method capable of lowering a gate electrode height, preventing piercing of B through a gate insulating film and suppressing an increase in parasitic capacitances of the source/drain regions.

Still another object of the present invention is to provide a semiconductor device having a pMOS transistor which has good stability, can operate at high speed, has a large drive current and can suppress the short channel effects.

Another object of the present invention is to provide a semiconductor device having a pMOS transistor which can constrain a gate electrode height, suppress B impurities from piercing through the gate insulating film and entering the channel region, and reduce parasitic capacitances of the source/drain regions.

According to one aspect of the present invention, there is provided a method for manufacturing a semiconductor device comprising steps of: (a) forming a gate insulating film on a semiconductor substrate including a first conductivity type active region defined by an element isolation region; (b) depositing a gate electrode layer of polycrystalline semiconductor on the gate insulating film; (c) implanting impurity ions to transform an upper portion of the gate electrode layer into an amorphous layer; (d) patterning the gate electrode layer to form a gate electrode; (e) forming side wall spacers on side walls of the gate electrode at a temperature not crystallizing the amorphous layer; and (f) implanting impurity ions of a second conductivity type into the first conductivity type active region by using as a mask the gate electrode and the side wall spacers, to form high concentration source/drain regions.

According to another aspect of the present invention, there is provided a semiconductor device comprising: a semiconductor substrate including a first conductivity type active region defined by an element isolation region; a gate insulating film formed on the first conductivity type active region; a gate electrode of polycrystalline semiconductor formed on the gate insulating film, the gate electrode containing impurities and second conductivity type impurities; side wall spacers formed on side walls of the gate electrode; high concentration source/drain regions formed by implanting ions of the second conductivity type impurities into the first conductivity type active region outside of the side wall spacers, the high concentration source/drain regions not containing the impurities; and a channel region defined in the first conductivity type active region under the gate electrode, the channel region not substantially containing the second conductivity type impurities for doping into the gate electrode.

According to still another aspect of the present invention, there is provided a semiconductor device comprising: a single crystal semiconductor substrate including a first conductivity type active region defined by an element isolation region; a gate insulating film formed on the first conductivity type active region; a gate electrode formed on the gate insulating film, the gate electrode including a polycrystalline lower layer and an amorphous upper layer and containing impurities and second conductivity type impurities; side wall spacers formed on side walls of the gate electrode; single crystal source/drain regions formed by implanting ions of the second conductivity type impurities into the first conductivity type active region outside of the side wall spacers and not by implanting ions of the impurities; and a single crystal channel region defined in the first conductivity type active region under the gate electrode, the single crystal channel region not substantially containing the second conductivity type impurities for doping into the gate electrode.

### BRIEF DESCRIPTION OF THE DRAWINGS

FIGS. 1A and 1B are graphs showing the results of analyzing current technologies.

FIGS. 2A and 2B are graphs showing the effects of Ge ion implantation.

FIGS. 3A to 3H are cross sectional views of a semiconductor substrate illustrating main processes of a semiconductor device manufacture method according to an embodiment of the invention.

FIGS. 4A and 4B are a graph and a diagram explaining the functions of the embodiment of the invention.

FIGS. 5A to 5C are cross sectional views of a semiconductor device illustrating a semiconductor device manufacture method according to an example of conventional methods.

FIGS. 6A to 6C are cross sectional views of a semiconductor device illustrating a semiconductor device manufacture method according to another example of conventional methods.

### DESCRIPTION OF THE PREFERRED EMBODIMENTS

The present inventors have analyzed current technologies and studied possible methods for solving the conventional problems.

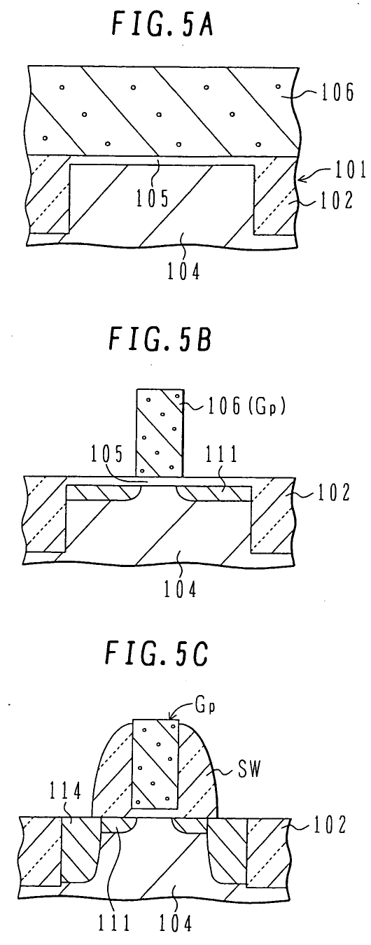

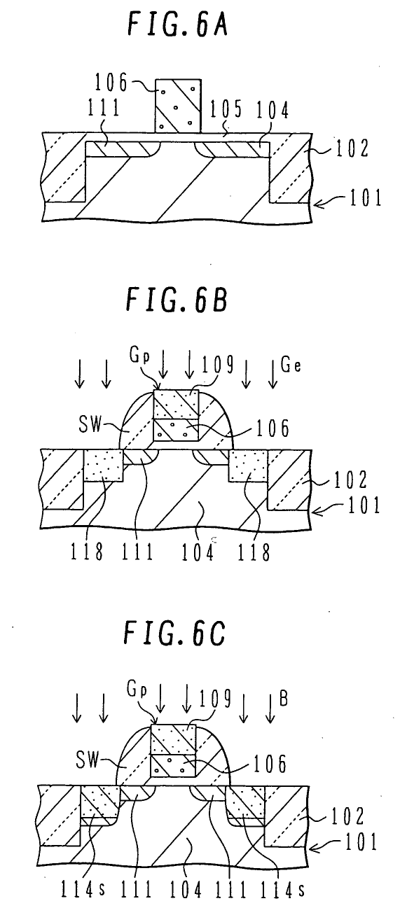

According to the technologies illustrated in FIGS. 5A to 5C, it is necessary to maintain high a gate electrode height in order to prevent B ions from piercing through the gate insulating film and entering the channel region. It has been found, however, as the gate electrode is maintained high and impurity activation is executed at a low temperature, impurities are not activated sufficiently and an obtained drain current reduces.

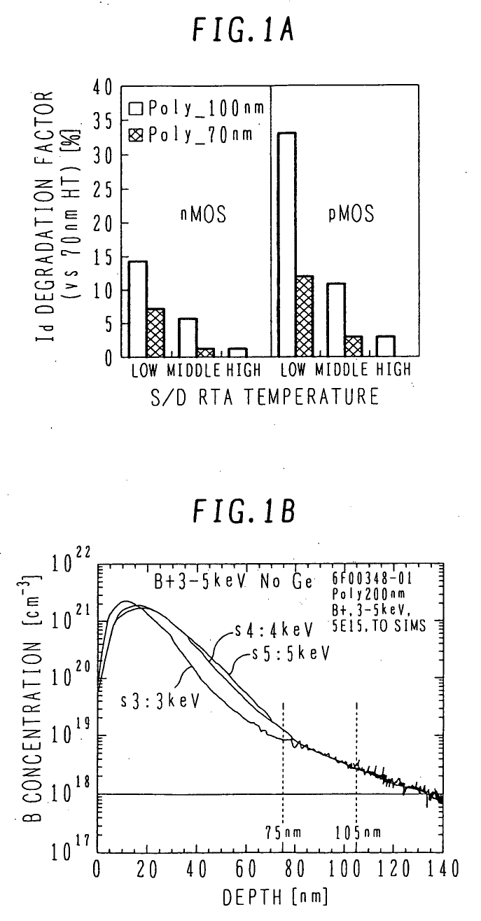

FIG. 1A is a graph showing a change in drain current of a pMOS transistor and an nMOS transistor in which the thicknesses of a polysilicon gate electrode were set to 100 nm and 70 nm, and after high concentration ions were implanted into the source/drain regions and gate electrode, rapid thermal annealing (RTA) was executed at low, middle and high temperatures.

The abscissa represents temperature, low, middle and high temperatures, and the ordinate represents a degradation factor of a drain current in the unit of % where a drain current Id of a transistor having a gate electrode height of 70 nm and annealed at a high temperature is set to 100%. The higher the percentage, the degradation is larger.

The measurement results of nMOS transistors are shown in the left area of FIG. 1A, and the measurement results of PMOS transistors are shown in the right area. In both the measurement results, as the activation heat treatment is performed at a lower temperature, the drain current Id reduces. The degradation of the drain current Id is larger for the gate electrode height of 100 nm than for the gate electrode height of 70 nm.

The degradation of the drain current is large, particularly for PMOS. The drain current Id of a pMOS transistor at a gate electrode height of 100 nm and at low temperature annealing degrades by 30% or more than that of a pMOS transistor at a gate electrode height of 70 nm and at high temperature annealing. If the gate electrode height is set to 70 nm, the degradation of the drain current Id is smaller than 15% even at low temperature annealing.

In order to suppress the degradation of the drain current, it is therefore desired to set the gate electrode height to 100 nm or lower. As the gate electrode height is lowered, there arises the problem of piercing of B ions through the gate insulating film when deep and high concentration source/drain regions of a pMOS transistor are formed.

FIG. 1B is a graph showing a distribution of B+ ions implanted into polysilicon layers. The abscissa represents a depth in the unit of nm and the ordinate represents a B concentration in a logarithmic scale of a unit of cm^{-3.}

Samples were formed by depositing a polysilicon layer having a thickness of 200 nm and by vertically implanting B+ ions at an acceleration energy of 3 to 5 keV and a dose of 5×10¹⁵ cm⁻². A distribution of a B concentration was measured by secondary ion mass spectroscopy (SIMS).

A curve s3 indicates the distribution of B in a depth direction when ion implantation is performed at an acceleration energy of 3 keV. Similarly, curves s4 and s5 indicate the distributions of B in the depth direction when ion implantation is performed at acceleration energies of 4 keV and 5 keV, respectively. As the acceleration energy is increased, the peak position of a B concentration moves to a deeper position. After the peak, the B concentration lowers. The curve s3 has a gentle reduction near at a depth of 40 nm. As compared to the curve s3, the curves s4 and s5 have B concentration lifted shapes from the peak to the depth of about 75 nm.

The distributions in the area at a depth of about 75 nm or deeper are generally the same, irrespective of the acceleration energy. No B concentration difference is recognized in the area at a depth of 80 nm or deeper, irrespective of the acceleration energy. At the depth of 75 nm, the B concentration is in the order of about 10¹⁹ cm⁻². At a depth of 105 nm, the B concentration eventually becomes higher than 2×10¹⁸ cm⁻². It can be anticipated from these results that as the gate electrode height is set low at 70 nm, a fair amount of B ions pierces through the gate insulating film and reaches the underlying channel region.

If B ions of a non-negligible amount pierce through the gate insulating film and enter the channel region, the threshold value of a pMOS transistor becomes unstable and the pMOS transistor cannot operate stably.

The B concentration distribution shown in FIG. 1B has a skirt portion that the concentration distribution does not lower proportionally as the depth becomes deeper. This abnormal impurity distribution is known, for example, as channeling in single crystal silicon. It can be considered that B ions show the channeling phenomenon also for polysilicon.

It is known that amorphousizing is effective for preventing channeling. It is also known that ion implantation of an element having a relatively large mass is effective for amorphousizing silicon single crystal. Conductivity imparting impurities such as As, Sb and In may be used. In order to avoid electric influences, neutral ions of the same group as that of silicon, Ge, Si and the like may be used. Ge among others has a large mass and is effective for amorphousizing.

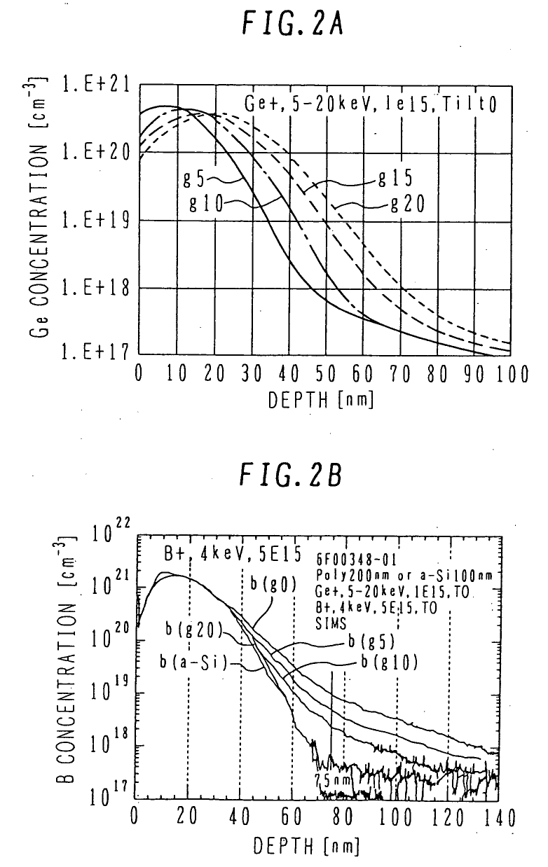

FIG. 2A is a graph showing the simulation results of a depth direction concentration distribution of Ge when Ge+ ions are implanted into polysilicon layers. The abscissa represents a depth in the unit of nm and the ordinate represents a Ge concentration in a logarithmic scale of a unit cm⁻³. A curve g5 indicates a Ge concentration distribution when Ge+ ions are implanted at an acceleration energy of 5 keV. Similarly, curves g10, g15 and g20 indicate Ge concentration distributions when Ge+ ions are implanted at acceleration energies of 10 keV, 15 keV and 20 keV, respectively. A dose is 1×10¹⁵ cm⁻² for all the cases.

As the acceleration energy increases, the peak value of the Ge concentration distribution moves to a deeper position and the whole concentration distribution moves to the deeper position. At the Ge concentration of 1×10¹⁹ atoms cm⁻³, as the acceleration energy is increased from 5 keV, to 10 keV, to 15 keV and to 20 keV, the depth becomes deeper from about 33 nm, to about 41 nm, to about 50 nm and to about 56 nm.

FIG. 2B is a graph showing a B concentration distribution when B⁺ ions are implanted into polysilicon layers amorphousized by Ge⁺ ion implantation. B⁺ ions were implanted at an acceleration energy of 4 keV and a dose of 5×10¹⁵ cm⁻². The abscissa represents a depth in a polysilicon layer in the unit of nm and the ordinate represents a B concentration in a logarithmic scale of a unit of cm⁻³. Before B⁺ ions were implanted, Ge⁺ ions were implanted at various acceleration energies and at a constant dose of 1×10¹⁵ cm⁻².

A curve b (g5) indicates a B concentration distribution when B⁺ ions are implanted after Ge ions are implanted at an acceleration energy of 5 keV. Similarly, curves b (g10) and b (g20) indicate B concentration distributions when B⁺ ions are implanted after Ge ions are implanted at acceleration energies of 10 keV and 20 keV, respectively. A curve b (g0) indicates a B concentration distribution when Ge ions are not implanted. A curve b (a-Si) indicates a B concentration distribution when B⁺ ions are implanted into an amorphous silicon layer instead of a polysilicon layer.

Although the curve b (g0) has a large skirt portion, the curve b (a-Si) has almost no skirt portion, indicating that the amorphous layer is effective for suppressing the abnormal distribution. The curve b (g20) has generally the same distribution as that of the curve b (a-Si), indicating that as Ge⁺ ions are implanted by about 1×10¹⁵ cm⁻² at an acceleration energy of 20 keV, generally the same results as those of the amorphous silicon layer can be obtained.

Although the curve b (g5) shows the suppression of the abnormal distribution as compared to the curve b (g0) without Ge ion implantation, the suppression effects are limited. It can be considered that the acceleration energy of Ge⁺ ions of 5 keV is insufficient.

The curve b (g10) has a distribution like that of the curve b (g20), particularly in the shallow region, and suppresses the abnormal distribution considerably. Although it has a skirt in the deep region, its width is limited.

The B concentrations at a depth of 75 nm of the curves b (g0), b (g5), b (g10) and b (g20) are higher than 1×10¹⁹ cm⁻³, 6×10¹⁸ cm⁻³, 3×10¹⁸ cm⁻³, and about 5×10¹⁷ cm⁻³, respectively.

In order to suppress the B abnormal distribution, it can be considered that Ge ion implantation is executed in an acceleration energy range of 10 keV to 20 keV. The suppression effects are small at an acceleration energy lower than 10 keV. At an acceleration energy higher than 20 keV, it is hard to expect the suppression effects to be improved more. Conversely, there is a possibility that Ge pierces through the gate insulating film and is doped in the channel region, adversely affecting the electric characteristics of the channel region.

It is confirmed that an amorphous layer formed by implanting Ge ions into the gate electrode prior to B ion implantation into the source/drain regions and gate electrode, is effective for constraining the depth of the subsequent B ion implantation. However, if Ge ions are implanted into the silicon substrate, the source/drain regions become shallow. It is preferable not to perform Ge⁺ ion implantation into the silicon substrate in order to widen the B concentration distribution in the source/drain regions, to form a junction at a sufficiently deep position, and to reduce parasitic capacitances.

In the following, description will be made on main processes of a semiconductor device manufacture method according to an embodiment of the invention.

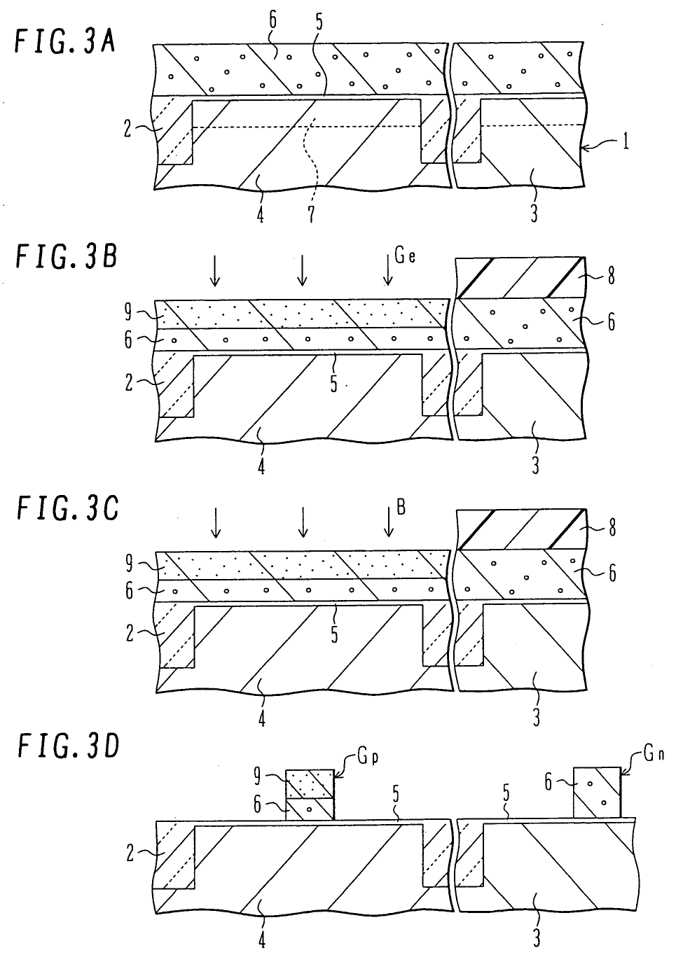

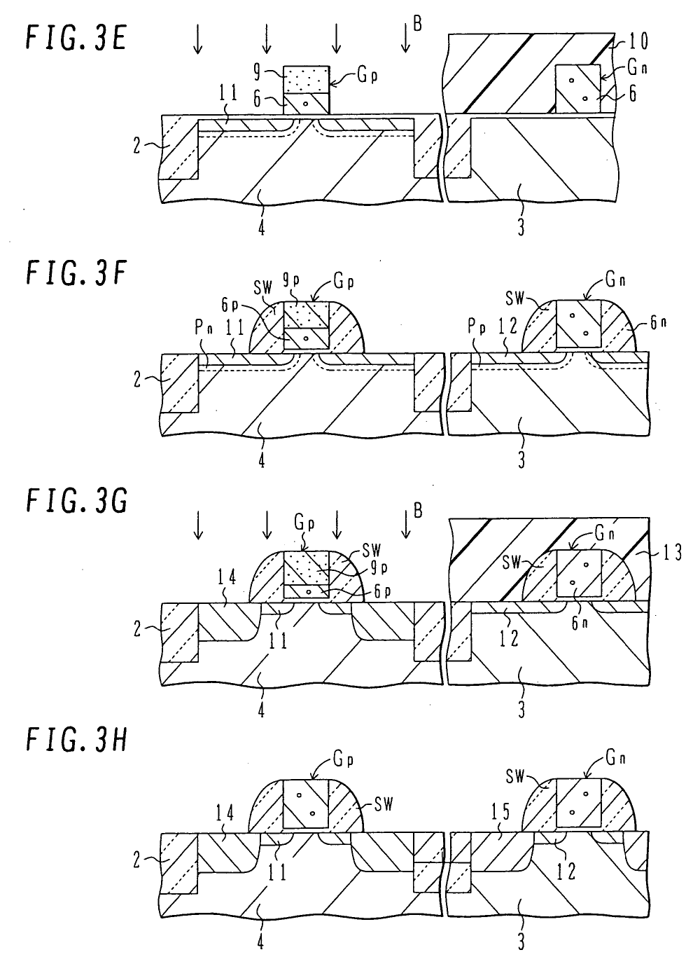

As shown in FIG. 3A, an element isolation region 2 is formed in the surface layer of a silicon substrate 1 by STI. Necessary ion implantation into an active region defined by the element isolation region is performed to form a p-type well 3 and an n-type well 4. Ion implantation for each well includes ion implantation processes for well forming, parasitic transistor prevention, threshold value adjustment and the like. A region 7 above a broken line has a high impurity concentration caused by threshold adjustment ion implantation.

After the wells are formed, a gate oxide film 5 having a thickness of, e.g., about 1 nm, is formed on the clean surface of the active region, by thermal oxidation. On the gate oxide film 5, a polysilicon layer 6 thinner than 100 nm, e.g., about 75 nm, is formed by thermal CVD.

As shown in FIG. 3B, a resist mask 8 is formed on the polysilicon layer 6 in the nMOS (p-well) region 3, and Ge⁺ ions are implanted into the polysilicon layer 6 in the PMOS region at an acceleration energy of 20 keV and a dose of 1×10¹⁵ cm⁻². With this Ge ion implantation, an upper portion of the polysilicon layer 6 is transformed into an amorphous silicon layer 9.

Ge ion implantation is preferably executed in an acceleration energy range of 10 keV to 20 keV. At an acceleration energy lower than 10 keV, the amorphousizing effects are small and the abnormal distribution suppression effects of the subsequent B ion implantation are small. At the acceleration energy of 20 keV, B ion implantation presents the sufficient abnormal distribution suppression effects approximately equal to those of a-Si.

As shown in FIG. 3C, by using the same resist mask 8, B⁺ ions are implanted, for example, at an acceleration energy of 3 keV and a dose of 2×10¹⁵ cm⁻². This B ion implantation is executed if the B ion concentration of the gate electrode of the pMOS transistor becomes insufficient only by a subsequent B ion implantation. The amorphous layer 9 suppresses a B abnormal distribution in the depth direction.

If the subsequent B ion implantation provides a sufficiently high concentration, the above-described B ion implantation may be omitted. In this case, the mask 8 may be omitted for Ge ion implantation shown in FIG. 3B. As Ge ion implantation is performed for the whole region of the polysilicon layer 6, the abnormal distribution suppression effects by the subsequent ion implantation can be obtained in the whole region.

The execution order of the processes shown in FIGS. 3B and 3C may be reversed. In this case, the acceleration energy for B ion implantation is set in order for B ions not to enter the channel region. After the upper portion of the gate electrode layer is transformed into an amorphous layer, heat treatment which transforms the amorphous layer into a polysilicon layer should not be executed until an objective ion implantation is executed. A heating temperature is desired to be set to 600° C. or lower, more preferably 500° C. or lower.

As shown in FIG. 3D, a resist layer is formed on the gate electrode layer 6 (9), a gate electrode pattern is exposed by using an ArF exposure system and a resist pattern is developed. Thereafter, the gate electrode layer is patterned by RIE to form gate electrodes Gp and Gn. For example, the gate length of the gate electrodes Gp and Gn is set to 30 nm. The resist pattern is thereafter removed.

As shown in FIG. 3E, the nMOS region is covered with a resist mask 10, and by using the gate electrode Gp as a mask in the pMOS region, B ions are implanted to form source/drain extension regions. For example, B⁺ ions are implanted at an acceleration energy of 0.5 keV and a dose of 1×10¹⁵ cm⁻².

Since the acceleration energy is low and the upper portion of the gate electrode layer is the amorphous layer 9, implanted B ions will not pierce through the gate insulating film. P⁺ ions are implanted at an acceleration energy of 10 keV and a dose of 1×10¹³ cm⁻² to form pocket regions Pn. The pocket regions are effective for suppressing the short channel effects.

After the resist mask 10 is removed, a new mask is formed covering the PMOS region and ion implantation processes for the nMOS region are performed to form shallow n-type extension regions and p-type pocket regions. For example, As as n-type impurities is implanted at an acceleration energy of 1 keV and a dose of 1×10¹⁵ cm⁻², and B as p-type impurities is implanted at an acceleration energy of 7 keV and a dose of 1×10¹³ cm⁻².

As shown in FIG. 3F, in the pMOS region, the p-type extension regions 11 and n-type pocket regions Pn are formed. In the nMOS region, n-type extension regions 12 and p-type pocket regions Pp are therefore formed. In the drawings to follow, the pocket regions are not shown.

A silicon oxide film having a thickness of, e.g., 80 nm, is deposited on the whole surface of the silicon substrate by low temperature CVD at a temperature of, e.g., 600° C. The silicon oxide film is subjected to reactive ion etching (RIE) to remove the silicon oxide on the flat surface. Side wall spacers SW of the silicon oxide film are therefore formed only on the side walls of the gate electrodes Gp and Gn.

As shown in FIG. 3G, a resist mask 13 is formed covering the nMOS region, and in the pMOS region, by using the side wall spaces SW as a mask, ion implantation is performed to form deep high concentration source/drain regions. For example, B⁺ ions are implanted at an acceleration energy of 3 keV and a dose of 4×10¹⁵ cm⁻².

Therefore, p-type impurity ions B are implanted into the gate electrode Gp made of a lamination of the amorphous silicon layer and polysilicon layer and into the single crystal silicon regions outside the side wall spacers SW. A B abnormal distribution in the gate electrode Gp is suppressed by the amorphous silicon layer 9p. The channel region (n-well) 4 under the gate electrode does not substantially undergo B ion implantation.

If the whole thickness of the gate electrode layer is transformed into an amorphous layer, impurities under the gate electrode are not sufficiently activated by subsequent activation, and activation insufficiency occurs. As the polysilicon layer 6p itself is used as the lower portion of the gate electrode, subsequent impurity activation can be performed properly.

Since an amorphous layer does not exist in the single crystal region, B ions are distributed deeply having a skirt portion, and it becomes possible to form the source/drain regions 14 deep enough to form small junction capacitances.

After the ion implantation for the source/drain regions in the pMOS region, the resist mask 13 is removed and a new resist mask is formed covering the pMOS region. In the nMOS region, for example, P⁺ ions are implanted at an acceleration energy of 6 keV and a dose of 5×10¹⁵ cm⁻² to form deep high concentration n-type source/drain regions. Even if an amorphous layer does not exist in an nMOS transistor, there is no problem because piercing of n-type impurity P through the gate insulating film is not still recognized.

However, if the gate electrode becomes further low, there is a possibility that n-type impurity P pierces through the gate insulating film. In this case, the Ge ion implantation shown in FIG. 3B is performed for the whole polysilicon layer 6 so that the channeling suppressing effects can be expected relative to n-type impurity ion implantation.

As shown in FIG. 3H, the deep n-type source/drain regions 15 are therefore formed also in the nMOS region. Thereafter, spike annealing is performed for 0 second at 1000° C. to 1050° C. to activate implanted impurity ions. The p-type impurities and n-type impurities are activated and the amorphous silicon layer in the upper portion of the gate electrode is transformed into a polysilicon layer. The polysilicon layer 6 in the lower portion of the gate electrode is effective for suppressing impurity activation insufficiency.

In the above manner, a pMOS transistor and an nMOS transistor are formed. Thereafter, by using well-known processes, an interlayer insulating film, lead wirings, multilayer wirings and the like are formed to complete a semiconductor integrated circuit device. For general semiconductor integrated circuit manufacture processes, for example, refer to U.S. Pat. Nos. 6,465,829, 6,492,734, and 6,707,156, and US publication U.S. 2003/0227086 A1, the whole contents of which are incorporated herein by reference.

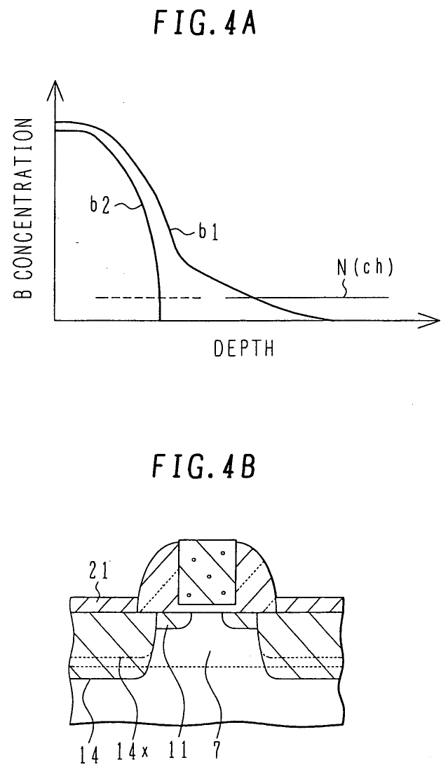

FIG. 4A is a graph showing briefly an impurity concentration distribution when deep source/drain regions are formed by the above-described PMOS transistor manufacture processes. In the above-described embodiment, since the source/drain regions are not subjected to amorphousizing, implanted B ions have a distribution b1 having a skirt portion or tail. If the source/drain regions are subjected to amorphousizing, implanted B ions have a distribution b2 steeply lowering the B concentration.

If the concentration of the channel region is N (ch), the junction depth formed by the concentration distribution b2 becomes much shallower than the junction depth formed by the concentration distribution b1, and the B concentration lowers sharply near the junction.

In the case of the junction formed by the concentration distribution b1, the p-type impurity concentration gently lowers near the junction, and a broad depletion can be formed easily. It is therefore possible to maintain small the parasitic capacitances of the source/drain regions. In the case of the junction formed by the concentration distribution b2, p-type impurity concentration lowers steeply near the junction. Formation of a broad depletion is suppressed and the parasitic capacitances of the source/drain regions become large.

Since the gate electrode has the amorphous layer, the concentration distribution with the skirt portion shown by the curve b1 is not formed, but the junction depth is constrained as indicated by the curve b2. It is therefore possible to efficiently prevent B ions from piercing through the gate insulating film.

B impurities are not substantially doped into the channel region under the gate electrode. The channel region under the gate electrode does not substantially contain B impurities used for doping into the gate electrode and has the B concentration distribution substantially the same as that of the regions under the side wall spacers SW. The term “substantially” has a meaning to be used when the electric characteristics are taken into consideration.

FIG. 4B is a schematic cross sectional view showing the structure of the above-described pMOS transistor. The deep source/drain regions 14 continuous with the extension regions 11 form junctions at the position deeper than a threshold value adjustment region 7. Therefore, the parasitic capacitances of the source/drain regions can be maintained small.

If the active region surface is amorphousized, the B concentration distribution is constrained when the source/drain regions are formed, and shallow source/drain regions 14x are formed. The impurity concentration distribution changes steeply, and as described above, the depletion of the p-type source/drain regions 14x is constrained and the parasitic capacitances of the source/drain regions increase.

The impurity concentration of the channel region changes in the depth direction with the threshold value adjustment ion implantation and the like. As the junction depth moves into the threshold value adjustment region 7, the impurity concentration of the channel region increases and the high concentration p-type region contacts the high concentration n-type region, so that a large parasitic capacitance is formed.

If a suicide layer 21 is formed on the substrate surface, a distance between the suicide layer and the pn junction becomes short, forming the reason of leak current. Since the deep source/drain regions 14 are formed, it is possible to suppress an increase in leak current even if the silicide layer 21 is formed.

The present invention has been described in connection with the preferred embodiments. The invention is not limited only to the above embodiments. For example, process parameters can be changed in various ways in accordance with the design. A plurality type of transistors and different type of elements such as passive elements can be integrated. It will be apparent to those skilled in the art that other various modifications, improvements, combinations, and the like can be made.

The above-described embodiments are suitable for semiconductor integrated circuit devices of high integration degree.

1. A method for manufacturing a semiconductor device comprising the steps of:
(a) forming a gate insulating film on a semiconductor substrate including a first conductivity type active region defined by an element isolation region;
(b) depositing a gate electrode layer of polycrystalline semiconductor on said gate insulating film;
(c) implanting first kind of ions to transform an upper portion of said gate electrode layer into an amorphous layer;
(d) patterning said gate electrode layer to form a gate electrode;
(e) forming side wall spacers on side walls of said gate electrode at a temperature not crystallizing said amorphous layer; and
(f) implanting second kind of ions of conductivity affording impurity having a second conductivity type opposite to said first conductivity type, into said first conductivity type active region by using as a mask said gate electrode and said side wall spacers, to form high concentration source/drain regions.

2. The method for manufacturing a semiconductor device according to claim 1, wherein said semiconductor is silicon and said first kind of ions are Ge or Si.

3. The method for manufacturing a semiconductor device according to claim 2, wherein the temperature not crystallizing said amorphous layer is at most 600° C.

4. The method for manufacturing a semiconductor device according to claim 2, wherein said first conductivity type is n-type, said second conductivity type is p-type, and said second kind of ions are B.

5. The method for manufacturing a semiconductor device according to claim 1, further comprising the step of:
(g) before said step (e), implanting third kind of ions of conductivity affording impurity having the second conductivity type, into said first conductivity type active region by using said gate electrode as a mask, to form source/drain extension regions.

6. The method for manufacturing a semiconductor device according to claim 1, wherein said semiconductor substrate includes said first conductivity type active region and a second conductivity type active region, said step (d) forms first and second gate electrodes above said first and second conductivity type active regions, and said step (e) forms side wall spacers on side walls of said first and second gate electrodes;
the method further comprising the step of:
(f-1) implanting first conductivity type impurity ions into said second conductivity type active region by using said second gate electrode and said side wall spacers on the side walls thereof as a mask to form high concentration source/drain regions.

7. The method for manufacturing a semiconductor device according to claim 6, wherein said step (c) is executed while covering said second conductivity type active region with a shield resist mask;
the method further comprises the step of:
(h) preliminary implanting impurity ions of the second conductivity type into said gate electrode layer by using the same shield resist mask.

8. A semiconductor device comprising:
a semiconductor substrate including a first conductivity type active region defined by an element isolation region;
a gate insulating film formed on said first conductivity type active region;
a gate electrode of polycrystalline semiconductor formed on said gate insulating film, said gate electrode containing amorphousizing atoms and second conductivity type impurities;
side wall spacers formed on side walls of said gate electrode;
high concentration source/drain regions formed by implanting ions of said second conductivity type impurities into said first conductivity type active region outside of said side wall spacers, said high concentration source/drain regions not containing said amorphousizing atoms; and
a channel region defined in said first conductivity type active region under said gate electrode, said channel region not substantially containing said second conductivity type impurities for doping into said gate electrode.

9. The semiconductor device according to claim 8, wherein said semiconductor is silicon and said amorphousizing atoms are Ge or Si.

10. The semiconductor device according to claim 9, wherein said first conductivity type is an n-type, said second conductivity type is a p-type, and said second conductivity type impurities are B.

11. The semiconductor device according to claim 10, wherein said gate electrode has a height lower than 100 nm.

12. The semiconductor device according to claim 8, further comprising source/drain extension regions formed by implanting ions of said second conductivity type impurities into said first conductivity type active region outside of said gate electrode.

13. The semiconductor device according to claim 8 wherein:
said semiconductor substrate further includes a second conductivity type active region; and
the semiconductor device further comprises:
another gate insulating film formed on said second conductivity type active region;
another gate electrode of polycrystalline semiconductor formed on said another gate insulating film, said another gate electrode containing first conductivity type impurities;
other side wall spacers formed on side walls of said another gate electrode; and
other high concentration source/drain regions formed by implanting ions of said first conductivity type impurities into said second conductivity type active region outside of said other side wall spacers.

14. The semiconductor device according to claim 13, wherein said other gate electrode contains said amorphousizing atoms, and another channel region defined between said other high concentration source/drain regions under said other gate electrode do not substantially contain said first conductivity type impurities.

15. A semiconductor device comprising:
a single crystal semiconductor substrate including a first conductivity type active region defined by an element isolation region;
a gate insulating film formed on said first conductivity type active region;
a gate electrode formed on said gate insulating film, said gate electrode including a polycrystalline lower layer and an amorphous upper layer and containing amorphousizing atoms and second conductivity type impurities;
side wall spacers formed on side walls of said gate electrode;
single crystal source/drain regions formed by implanting ions of said second conductivity type impurities into said first conductivity type active region outside of said side wall spacers and not implanted with said amorphousizing atoms; and
a single crystal channel region defined in said first conductivity type active region under said gate electrode, said single crystal channel region not substantially containing said second conductivity type impurities for doping into said gate electrode.

16. The semiconductor device according to claim 15, wherein said single crystal semiconductor substrate is a silicon substrate, said amorphousizing atoms are Ge or Si, said first conductivity type is n-type, said second conductivity type is p-type, and said second conductivity type impurities are B.

17. The semiconductor device according to claim 15, further comprising source/drain extension regions formed by implanting ions of said second conductivity type impurities into said first conductivity type active region outside of said gate electrode.
